(19) United States
(12) Patent Application Publication
(10) Pub. No.: US 2025/0194107 A1
(43) Pub. Date: Jun. 12, 2025

(54) MATERIALS FOR SWITCHING ELEMENTS, SWITCHING ELEMENTS AND METHODS FOR MANUFACTURING SWITCHING ELEMENTS

(71) Applicant: UIF (University Industry Foundation), Yonsei University, Seoul (KR)

(72) Inventors: Hyun Chul SOHN, Seoul (KR); Wan Sun KIM, Seoul (KR); Ju Sung KIM, Seoul (KR)

(73) Assignee: UIF (University Industry Foundation), Yonsei University, Seoul (KR)

(21) Appl. No.: 18/968,437

(22) Filed: Dec. 4, 2024

(30) Foreign Application Priority Data
Dec. 6, 2023 (KR) 10-2023-0175300

(51) Int. Cl. H10B 63/00; C23C 14/04; C23C 14/06; C23C 14/34; H10N 70/00

(52) U.S. Cl. CPC H10B 63/24; C23C 14/042; C23C 14/0629; C23C 14/34; H10N 70/026; H10N 70/841; H10N 70/8828; H10N 70/883

(57) ABSTRACT

A material for a switching element, a switching element including the same, and a method for manufacturing the switching element are disclosed. The material for the switching element includes CrTe and has OTS (Ovonic Threshold Switch) switching characteristics.

### CROSS-REFERENCE TO RELATED APPLICATION

This application claims priority to Korean Patent Application No. 10-2023-0175300 filed on Dec. 6, 2023 in the Korean Intellectual Property Office, and all the benefits accruing therefrom under 35 U.S.C. 119, the contents of which are herein incorporated by reference in its entirety.

### BACKGROUND

### Field

The present disclosure relates to a material for a switching element, a switching element, and a method for manufacturing a switching element.

### Description of Related Art

A three-dimensional crossbar structure has a simple structure and a high integration level under an important development in next-generation memory technology. However, in this structure, a need for a select element arises due to leakage current occurring during a memory read operation. An OTS (Ovonic Threshold Switch) material is being studied for the select element, and exhibits rapid current increase above a threshold voltage (VTH). A PcRAM element generally provides excellent write and comparable read performance, and operates in a high current area. Accordingly, a select element with high on-current is required in a 1S1R structure (a structure in which one select element and one memory element are combined with each other) of a 3D crossbar structure. In this regard, a read disturb phenomenon caused by a difference between operating currents of PcRAM and OTS is recognized as a major problem in the PcRAM element. This phenomenon occurs due to the difference between ION of the selector and the ION of the memory, i.e., the limitation of a read window. A problem occurs in the reliability of the element due to the sneak current flowing in the unselected cell. To solve this problem, introduction of a selector with high current characteristics is necessary, which contributes to significantly improving the performance and reliability of the PcRAM element.

### SUMMARY

A purpose of the present disclosure is to secure high on-current characteristics in order to enable smooth operation of the memory element in the 1S1R element. To this end, the inventors of the present disclosure have invented a select element with high on-current characteristics using CrTe material. Specifically, a purpose of the present disclosure is to improve the performance and reliability of the switching element. In particular, it is important to ensure fast and efficient current increase and switching operation above the threshold voltage in the switching element. To this end, according to the present disclosure, a high-performance switching unit is formed via co-sputtering of CrTe, Te, and ZnTe, and is effectively integrated with first and second electrodes. This highly integrated switching element ensures high current capacity and fast response time, and enables precise electrical control required in complex electronic systems. Furthermore, according to the present disclosure, a patterning technique utilizing a mask is employed to increase the precision in a manufacturing process of the switching element, thereby precisely controlling the position and shape of the switching unit. This contributes to ensuring consistent performance and high reliability of the element. In conclusion, the purpose of the present disclosure is to realize improved performance and efficient operation of the electronic device through the development of the high-performance, high-reliability switching element.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides a material for a switching element, wherein the material includes CrTe and has OTS (Ovonic Threshold Switch) switching characteristics.

In accordance with some embodiments of the material for the switching element, the material for the switching element is prepared by co-sputtering CrTe, Te, and ZnTe.

A second aspect of the present disclosure provides a switching element comprising: a switching unit including a material for a switching element, wherein the material includes CrTe, and has OTS (Ovonic Threshold Switch) switching characteristics; and a first electrode and a second electrode respectively contacting the switching unit and spaced apart from each other.

In accordance with some embodiments of the switching element, the first electrode or the second electrode includes TiN.

In accordance with some embodiments of the switching element, the switching element further comprises a lower substrate, wherein the lower substrate includes the first electrode, wherein the switching unit is formed on at least the first electrode, wherein the second electrode is formed on the switching unit.

In accordance with some embodiments of the switching element, the lower substrate includes at least one conductive substrate and at least one insulating substrate formed on the conductive substrate, wherein the first electrode extends through the insulating substrate so as to contact the conductive substrate.

In accordance with some embodiments of the switching element, the first electrode includes a plurality of first electrodes, the second electrode includes a plurality of second electrodes, and the switching unit includes a plurality of switching units.

In accordance with some embodiments of the switching element, the switching unit is formed by co-sputtering of CrTe, Te, and ZnTe.

A third aspect of the present disclosure provides a method for manufacturing a switching element, the method comprising: a first step of forming a switching unit on a first electrode, wherein the switching unit includes a material for a switching element, wherein the material includes CrTe, and has OTS (Ovonic Threshold Switch) switching characteristics; and a second step of forming a second electrode on the switching unit.

In accordance with some embodiments of the method for manufacturing the switching element, the switching unit is formed by co-sputtering of CrTe, Te, and ZnTe.

In accordance with some embodiments of the method for manufacturing the switching element, the switching unit is formed on each of a plurality of first electrodes formed on a substrate, wherein the method further comprises: prior to the forming of the switching unit, a step of forming a mask on an area of the substrate except for an area thereof on which the plurality of first electrodes have been formed; and after the forming of the switching unit or after the forming of the second electrode, a step of lifting off the mask.

In accordance with some embodiments of the method for manufacturing the switching element, the first electrode or the second electrode includes TiN.

According to the present disclosure, the on current of the select element may be increased and the selectivity thereof may be increased. It is expected that this will enable improved compatibility thereof with various memory elements and smooth operation for implementing a high-density 3D cross-point array structure of next-generation memory. The switching element of the present disclosure may be applied to all fields where non-volatile memory is used, such as personal computers and data centers, and may lead the industrial development of semiconductor memory technology, and may become a new indicator for the development of next-generation memory. Specifically, the effect of the present disclosure is to significantly improve the performance and efficiency of the switching element. The switching element manufactured using the method of the present disclosure provides higher current capacity and faster switching response time. The switching unit formed by co-sputtering of CrTe, Te, and ZnTe enables rapid current increase and efficient switching at the threshold voltage, which improves the overall performance of the electronic device. Furthermore, according to the present disclosure, the electrical signal processing precision may be improved via the precise integration between the first and second electrodes and the switching unit. The precise patterning using the mask precisely controls the position and the size of the switching unit, ensuring reliability and consistent performance of the element. These improved characteristics are particularly important in fields such as high-performance computing, data storage, and high-speed communications. In the end, the present disclosure greatly contributes to overcoming the technical limitations of the switching element and maximizing the performance of the electronic device.

In addition to the effects as described above, specific effects in accordance with the present disclosure will be described together with following detailed descriptions for carrying out the disclosure.

### BRIEF DESCRIPTION OF DRAWINGS

FIG. 1 illustrates an example of a switching element according to an embodiment of the present disclosure.

FIG. 2 is a diagram showing an example of a process for co-sputtering a switching unit of a switching element according to an embodiment of the present disclosure.

FIG. 3 to FIG. 7 are diagrams showing a manufacturing process and an experimental method of a switching element of the present disclosure.

FIG. 8 is a diagram showing a result of an experimental example of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in the present disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. In the context of the present disclosure, the term “about” may mean about ±1%, about ±2%, about ±3%, about ±4%, about #5%, about #6%, about ±7%, about ±8%, about ±9%, or about ±10% of a value stated herein.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

A material for a switching element according to an embodiment of the present disclosure may include CrTe and have OTS (Ovonic Threshold Switch) switching characteristics. In the context of the present disclosure, the OTS switching characteristic refers to a phenomenon in which the current of the element increases rapidly above a specific threshold voltage. Due to this characteristic, the switching element is maintained stably in a normal operating range, but when the voltage reaches the threshold voltage, the current increases rapidly to perform a switching operation. This is important for improving the selectivity and reliability of the switching element, and achieves the high integration level and enables an efficient switching operation. The present disclosure is at least based on the discovery that the material for the switching element including CrTe has OTS switching characteristics.

In one embodiment, the material for the switching element may be prepared by co-sputtering CrTe, Te, and ZnTe. In the context of the present disclosure, the meaning of the co-sputtering refers to a process of forming a thin film by simultaneously sputtering multiple target materials. Through this method, CrTe, Te, and ZnTe may be effectively mixed with each other to form a uniform thin film. The co-sputtering enables uniform mixing and precise composition control between materials, which plays an important role in optimizing the performance and stability of the switching element.

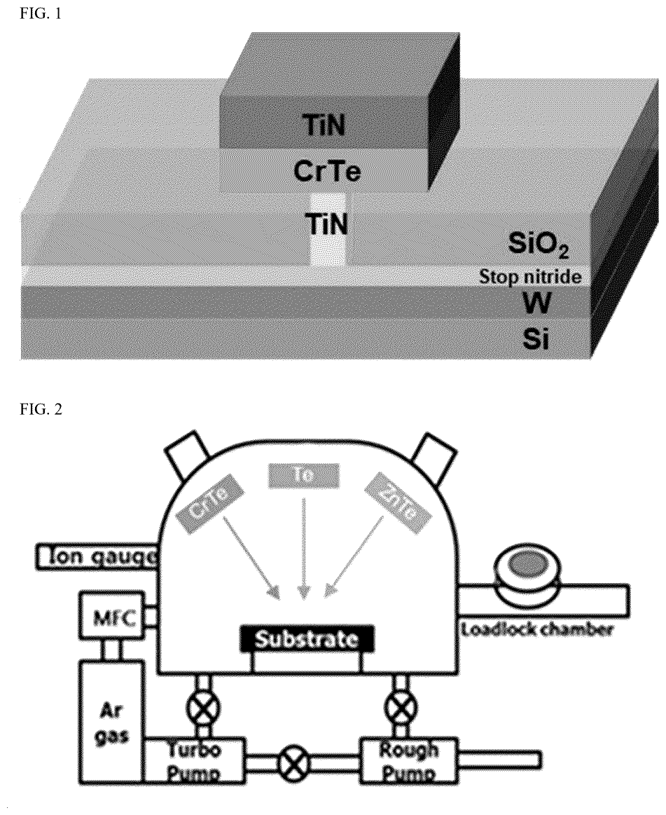

FIG. 1 illustrates an example of a switching element according to an embodiment of the present disclosure.

Referring to FIG. 1, a switching element according to an embodiment of the present disclosure may include a switching unit including a material for a switching element, the material including CrTe and having OTS (Ovonic Threshold Switch) switching characteristics; and a first electrode and a second electrode that are respectively in contact with the switching unit and spaced apart from each other.

The role of the switching unit is to enable a switching operation by inducing a rapid increase in current above a threshold voltage. The switching unit provides an electrical path between the first electrode and the second electrode, and is designed so that the current rapidly increases when the voltage reaches the threshold voltage. This process allows the switching element to operate at high efficiency, which is very important for applications that require high performance and reliability in various electronic devices. Therefore, the switching unit is a core portion of the switching element, and enables precise control of an electrical signal to enhance the overall operating efficiency of the switching element.

The role of the first electrode and the second electrode is to regulate and control the flow of current within the switching element. When the difference between voltages of these two electrodes exceeds the threshold voltage in the switching unit, the switching element is activated such that the current increases rapidly. These electrodes precisely control the operation of the switching element, and are especially important for maintaining the performance and stability of the element in high voltage and high current environments. The efficient design of the first and second electrodes improves the response speed and reliability of the switching element, which may be required for advanced electronic systems with high-speed switching requirements. Therefore, these two electrodes play an important role in enhancing the overall performance and efficiency of the switching element.

As long as the material of each of the first electrode and the second electrode plays the above role, the material of each of the first electrode and the second electrode is not particularly limited. In one embodiment, each of the first electrode or the second electrode may include TiN. TiN (Titanium Nitride) has high conductivity, excellent chemical stability, and strong wear resistance, thus making it suitable as an electrode material for a switching element. These characteristics help the switching element to operate stably for a long time. The selection of this material may ensure that the switching element maintains high reliability even in various operating environments.

The switching element according to an embodiment of the present disclosure does not particularly limit addition of another component thereto. In one embodiment, the switching element may include a lower substrate. In one embodiment, the lower substrate may include the first electrode. That is, for example, the lower substrate may be formed to have a portion including the first electrode. This structure may strengthen the electrical connection between the electrode and the substrate, and improve the structural stability of an entirety of the switching element.

In one embodiment, the switching unit may be formed on at least the first electrode. This configuration means that the switching unit as an important functional portion of the switching element is directly connected to the first electrode. This arrangement enables efficient transmission of the electrical signal and faster switching response. In one embodiment, the second electrode may be formed on the switching unit. This means that the two main components of the switching element, that is, the switching unit and the second electrode are directly interconnected to each other. This structure plays an important role in improving the overall performance of the switching element.

In one embodiment, the lower substrate may include at least one conductive substrate and at least one insulating substrate formed on the conductive substrate. The insulating substrate may prevent unnecessary current flow between the electrodes, thereby increasing the reliability of the element. In one embodiment, the first electrode may extend through the insulating substrate so as to contact the conductive substrate. This configuration allows the first electrode to efficiently transmit the electrical signal via the conductive substrate, while the insulating substrate prevents unnecessary current leakage to surrounding components. Such a design is important for optimizing electrical performance and improving overall reliability and stability of the element.

In one embodiment, the switching element may include a plurality of first electrodes, a plurality of second electrodes, and a plurality of switching units. This configuration means that the switching element may provide more complex and diverse electrical paths and functions via multiple electrodes and switching units. This greatly expands the versatility and diverse application possibilities of the switching element. For example, a design including the plurality of electrodes and the plurality of switching units enables a switching operation at higher current capacity, and improved signal processing capability, and under more precise control. Such a multi-configuration is particularly useful in complex and high-performance applications such as large-scale data processing, high-speed communications, or high-precision sensors.

In one embodiment, the switching unit may be formed by co-sputtering of CrTe, Te, and ZnTe. FIG. 2 is a diagram illustrating an example of a process of co-sputtering a switching unit of a switching element in accordance with an embodiment of the present disclosure. This process optimizes a material composition of the switching unit which performs the core function of the switching element. Using the co-sputtering technique may allow these three materials to be uniformly mixed with each other to form a highly integrated thin film, which is important for improving the electrical characteristics of the switching unit. The combination of CrTe, Te, and ZnTe allows the switching unit to switch quickly and efficiently at a specific threshold voltage, which contributes to improving the overall performance and responsiveness of the switching element. Furthermore, this material composition plays an important role in increasing the durability and reliability of the switching element, and meeting the requirements in a wide range of applications.

In the context of the present disclosure, the meaning of co-sputtering refers to a technology that simultaneously sputters multiple target materials, thereby uniformly mixing various materials with each other and depositing the mixture in a form of a thin film. In this process, various materials such as CrTe, Te, and ZnTe are sputtered together with each other such that the properties of the materials are combined with each other to form a thin film with an improved function. This thin film is applied to the switching unit as the core portion of the switching element, thereby providing fast responsiveness at the threshold voltage, high reliability, and excellent durability. The co-sputtering is a key process that enables uniform mixing between the materials, thereby allowing the switching element to operate stably even in a complex electronic environment.

In one embodiment of the present disclosure, the switching element may be manufactured to have the electrode having a thickness of about 75 nm and an area size of about 220 nm*220 nm, and the switching unit having a thickness of about 20 nm, and thus may have an on current of 8 to 12 mA.

Further, a method for manufacturing a switching element according to an embodiment of the present disclosure may include a first step of forming a switching unit on a first electrode, wherein the switching unit includes a material for a switching element, the material including CrTe and having OTS (Ovonic Threshold Switch) switching characteristics; and a second step of forming a second electrode on top of the switching unit. The role of the first step is to define the basic structure and function of the switching unit. In this step, the material for the switching element, that is, CrTe, is deposited on the first electrode to form the switching unit having a switching function in which the current therein increases rapidly when the voltage reaches the threshold voltage. Thereafter, in the second step, the second electrode is formed on top of the switching unit, thereby completing the overall circuit configuration of the switching element. This step is an important process that establishes the electrical path of the switching element and determines the overall performance and efficiency of the element. The switching unit formed between the first electrode and the second electrode enables the core operation of the switching element and provides precise electrical control required in high-performance electronic devices.

In one embodiment, the switching unit may be formed by co-sputtering of CrTe, Te, and ZnTe. In one embodiment, each of the switching units may be formed on each of a plurality of first electrodes formed on a substrate.

In one embodiment, prior to forming the switching unit, a step of forming a mask on an area of the substrate excluding an area of the plurality of first electrodes may be further included in the method. After forming the mask in this manner, the switching unit may be formed via the co-sputtering, thereby allowing precise control of the position and the size of the switching unit. The use of the mask ensures that the switching unit is deposited only on a specific area of the first electrode, which is important for more precise control of the current path within the switching element. Furthermore, the process of using the mask contributes to ensuring uniform thickness and consistent performance of the switching unit. This precise manufacturing process improves the overall performance and reliability of the switching element, and is particularly important in meeting the requirements of complex and precise electronic systems.

In the context of the present disclosure, the meaning of the mask refers to a barrier or template used to deposit or form a material in a specific area during the manufacturing process. In the manufacturing of the switching element, the mask allows the material for the switching element to be deposited only in the specific area, thereby preventing the material from being deposited in an undesired area. A type of the mask and the method of forming the mask are not particularly limited as long as the above function is performed using the mask and the method of forming the mask. For example, the mask may be formed in a manner in which photoresist is formed on an entire surface of the substrate, and only a portion of the photoresist corresponding to at least the plurality of first electrodes is removed.

After forming the switching unit and/or the second electrode only on top of the first electrode using the mask, the mask may be removed. In this regard, the method of removing the mask is not particularly limited. In one embodiment, the mask may be lifted off after the formation of the switching unit or the formation of the second electrode. In the lift-off process, the material formed on the mask may be removed together, leaving the switching unit and the electrode with a clean and accurate pattern. This process ensures that a microstructure of the switching element is precisely formed, and has a significant impact on the electrical characteristics and performance of the element. The removal of the mask via the lift-off contributes to increasing the efficiency of the manufacturing process and achieving high pattern precision. Such precise pattern formation enables the switching element to maintain high performance and meet the requirements of complex electronic circuits.

In one embodiment, the first electrode or the second electrode may include TiN.

Hereinafter, examples of the present disclosure are described in detail. However, the examples as described as set forth below are only some embodiments of the present disclosure, and the scope of the present disclosure is not limited to the examples as set forth below.

### Manufacturing Example

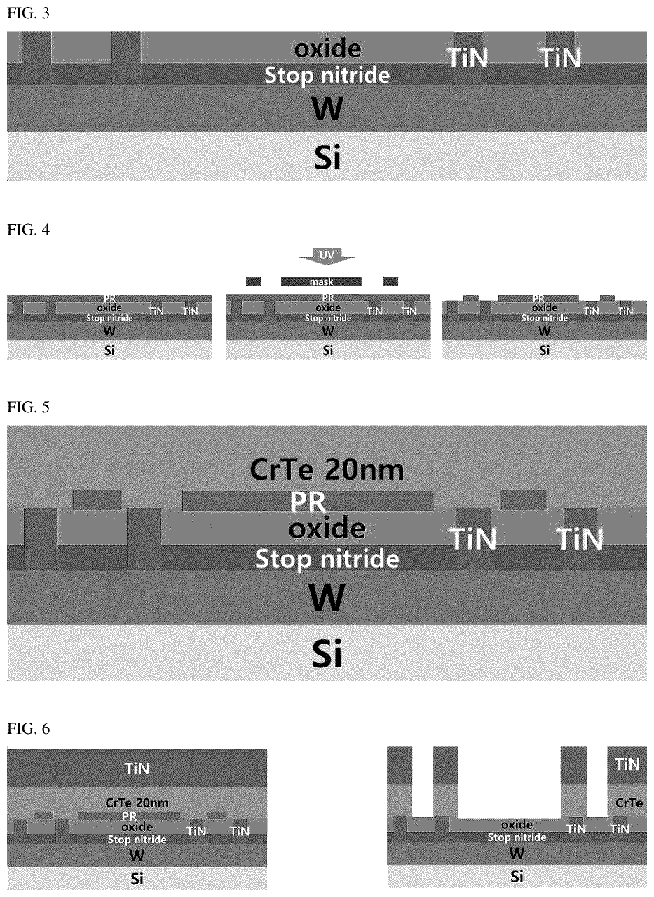

Step 1: Refer to FIG. 3. A TiN electrode substrate having a size of 220 nm is used to form the lower electrode. This TiN substrate provides excellent electrical properties and durability, thus forming a base of the switching element.

Step 2: Refer to FIG. 4. A patterning process for forming a MIM (Metal-Insulator-Metal) structure is performed. This step includes a process of spin-coating photoresist (PR), patterning the PR using UV light, and removing an unnecessary portion of the PR.

Step 3: Refer to FIG. 5. A 20 nm thick CrTe alloy thin film is formed. This process is performed by co-sputtering CrTe and Te using a RF magnetron sputtering scheme.

Step 4: Refer to FIG. 6. The upper electrode is formed. A DC magnetron sputtering scheme using a Ti metal target is performed to form a TiN upper electrode with a thickness of 100 nm. Then, the photoresist (PR) is removed using a lift off scheme to complete the pattern.

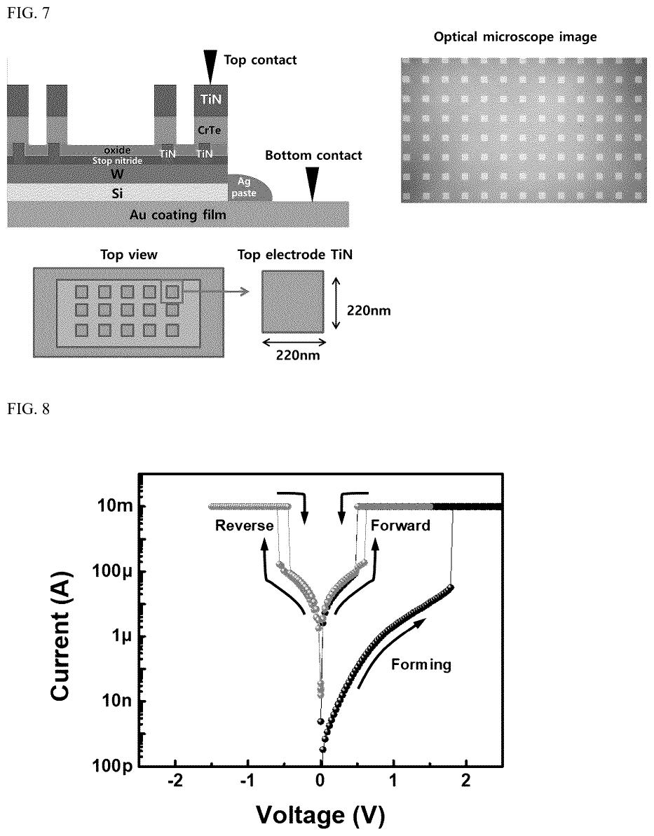

Step 5: Refer to FIG. 7. The B1500A equipment is used to measure electrical data. In this step, the electrical characteristics of the switching element are identified based on a measuring result of a typical IV (current-voltage) curve of the switching element.

### Experimental Example

The electrical characteristics of the switching element were identified in Step 5 as set forth above. FIG. 8 shows the result. Referring to FIG. 8, the electrical characteristics of the single CrTe element and the Te-based chalcogenide select element are compared with each other. In this regard, the CrTe thin film and the Te-based chalcogenide thin film are deposited via sputtering while TE (top electrode) is made of TiN and BE (bottom electrode) is made of TiN. Thus, the difference between electrical characteristics of the two elements may be identified. In the single CrTe thin film element, the ION is identified to be 10 mA. In the select element including the thin film made of each of GeTe, MnTe, GaTe, ZnTe, N doped GaTe, Zr doped GaTe, Ag doped GaTe, Zr doped ZnTe, (CrTe)(ZnTe), etc, the ION is identified to be 1 mA. Therefore, it is expected that the CrTe-based select element with high on-current characteristics will smoothly operate in the PcRAM-OTS integrated element.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects.

What is claimed is:

1. A material for a switching element, wherein the material includes CrTe and has OTS (Ovonic Threshold Switch) switching characteristics.

2. The material for the switching element of claim 1, wherein the material for the switching element is prepared by co-sputtering CrTe, Te, and ZnTe.

3. A switching element comprising:
a switching unit including a material for a switching element, wherein the material includes CrTe, and has OTS (Ovonic Threshold Switch) switching characteristics; and
a first electrode and a second electrode respectively contacting the switching unit and spaced apart from each other.

4. The switching element of claim 3, wherein the first electrode or the second electrode includes TiN.

5. The switching element of claim 3, wherein the switching element further comprises a lower substrate,
wherein the lower substrate includes the first electrode,
wherein the switching unit is formed on at least the first electrode,
wherein the second electrode is formed on the switching unit.

6. The switching element of claim 5, wherein the lower substrate includes at least one conductive substrate and at least one insulating substrate formed on the conductive substrate,
wherein the first electrode extends through the insulating substrate so as to contact the conductive substrate.

7. The switching element of claim 3, wherein the first electrode includes a plurality of first electrodes, the second electrode includes a plurality of second electrodes, and the switching unit includes a plurality of switching units.

8. The switching element of claim 3, wherein the switching unit is formed by co-sputtering of CrTe, Te, and ZnTe.

9. A method for manufacturing a switching element, the method comprising:
a first step of forming a switching unit on a first electrode, wherein the switching unit includes a material for a switching element, wherein the material includes CrTe, and has OTS (Ovonic Threshold Switch) switching characteristics; and
a second step of forming a second electrode on the switching unit.

10. The method for manufacturing the switching element of claim 9, wherein the switching unit is formed by co-sputtering of CrTe, Te, and ZnTe.

11. The method for manufacturing the switching element of claim 10, wherein the switching unit is formed on each of a plurality of first electrodes formed on a substrate,
wherein the method further comprises:
prior to the forming of the switching unit, a step of forming a mask on an area of the substrate except for an area thereof on which the plurality of first electrodes have been formed; and
after the forming of the switching unit or after the forming of the second electrode, a step of lifting off the mask.

12. The method for manufacturing the switching element of claim 9, wherein the first electrode or the second electrode includes TiN.
